(19) United States
(12) Patent Application Publication
(10) Pub. No.: US 2013/0077267 A1
(43) Pub. Date: Mar. 28, 2013

(54) POWER BOARD, METHOD OF MANUFACTURING THE SAME AND LIQUID CRYSTAL DISPLAY APPARATUS HAVING THE SAME

(71) Applicants: Jeong-il KANG, Yongin-si (KR); Shin-wook CHOI, Seoul (KR); Gil-yong CHANG, Suwon-si (KR)

(72) Inventors: Jeong-il KANG, Yongin-si (KR); Shin-wook CHOI, Seoul (KR); Gil-yong CHANG, Suwon-si (KR)

(73) Assignee: SAMSUNG ELECTRONICS CO., LTD., Suwon-si (KR)

(21) Appl. No.: 13/440,027

(22) Filed: Apr. 5, 2012

(30) Foreign Application Priority Data
Sep. 22, 2011 (KR) 2011-0095913

(51) Int. Cl. H05K 5/00; H05K 3/34

(52) U.S. Cl. 361/752; 29/840

(57) ABSTRACT

A power board is provided. The power board includes a board housing; a board included in an inside of the board housing; a plurality of parts mounted in the board; and a supporting member configured to be mounted in the board and to support the board to prevent each of the plurality of parts from being damaged. The supporting member includes a supporting member mounted by using a surface mounted technology (SMT) process.

### CROSS-REFERENCE TO RELATED APPLICATION

This application claims priority from Korean Patent Application No. 10-2011-0095913, filed on Sep. 22, 2011, in the Korean Intellectual Property Office, the disclosure of which is incorporated herein by reference in its entirety.

### BACKGROUND

1. Field

Apparatuses and methods consistent with exemplary embodiments relate to a power board, a method of manufacturing the same, and a liquid crystal display apparatus having the same.

2. Description of the Related Art

In the related art, liquid crystal display (LCD) apparatuses are configured to implement an image by using a liquid crystal, and applied to various kinds of display apparatuses, such as televisions and computer monitors.

In recent years, the LCD apparatuses have become smaller and thinner. Thus, an area occupied by circuits built in the products is very small. Because tops of parts mounted on a top and bottom of a circuit board are nearly in contact with a cover such as a housing, circuits are likely to be damaged by pressing of the cover due to a force applied from the exterior of the display apparatus, or by vibration or shock during the movement of the product. In particular, such a problem becomes serious in a power circuit board which uses many large parts. In the related art, when an external force is applied to an unstable space in which the circuits are located, a supporting member having a higher height than the respective parts of the circuits primarily absorbs the force in order to maintain the space, thereby preventing the parts on a top and bottom of a power circuit board from being damaged.

However, in the related art, because the supporting member is inserted manually into the circuit board after the parts are mounted and soldered in the board, there is a problem that a separate process of mounting the supporting member is inevitably required.

### SUMMARY

One or more exemplary embodiments may overcome the above disadvantages and other disadvantages not described above. However, it is understood that one or more exemplary embodiment are not required to overcome the disadvantages described above, and may not overcome any of the problems described above.

One or more exemplary embodiment provides a power board including a supporting member mounted in a board by using a surface mount technology (SMT) and a soldering process.

According to an aspect of an exemplary embodiment, there is provided a power board. The power board may include: a board housing; a board included in an inside of the board housing; a plurality of parts mounted in the board; and a supporting member which is mounted in the board and which supports the board to prevent each of the plurality of parts from being damaged. The supporting member may include a supporting member mounted by using a surface mounted technology (SMT) process.

The supporting member mounted by using the SMT process may be soldered and fixed to the board.

The supporting member may include a lower supporting unit which supports a bottom of the board, and a soldering unit attached to a side of the lower supporting unit and which is soldered and fixed to the bottom of the board.

The supporting member may further include an upper supporting unit which is formed on the lower supporting unit and which supports a top of the board.

A height of the lower supporting unit may be greater than a height of each part mounted on the bottom of the board.

The board may include a through-hole which allows the upper supporting unit to be inserted therethrough. The lower supporting unit may have a width greater than a width of the through-hole.

A height of a portion of the upper supporting unit extending from the top of the board may be greater than a height of each part mounted on the top of the board.

The supporting member may further include a hook unit which prevents the upper supporting unit from slipping through the through-hole.

The soldering unit may be formed such that the soldering unit is mounted to penetrate the lower supporting unit, and both of a first end and a second end opposite the first end of the soldering unit may be bent to be in contact with the bottom of the board.

Alternatively, the soldering unit may be formed such that a first end of the soldering unit is inserted into the lower supporting unit and a second end opposite the first end of the soldering unit is in contact with the bottom of the board.

A plurality of soldering units may be mounted in the lower supporting unit such that each respective soldering unit is spaced apart from a next soldering unit by a predetermined distance.

The supporting member may include an insulator formed by using a thermosetting resin. The supporting member may include a material which is heat-resistant at a soldering temperature.

According to another aspect of an exemplary embodiment, there is provided a method of manufacturing a power board. The method may include: mounting an upper part on a top of a board; mounting a lower part and a supporting member which supports the board to prevent the upper and lower parts from being damaged in a bottom of the board by using a surface mount technology (SMT) process; and soldering the lower part and the supporting member on the bottom of the board.

According to still another aspect of an exemplary embodiment, there is provided a liquid crystal display apparatus including any one of power boards according to exemplary embodiments.

According to various exemplary embodiments, because a supporting member is mounted on a board by a soldering after applying a SMT process, a separate process of mounting the supporting member is not required and thus an effect of improving productivity of a power board can be obtained.

Additional aspects and advantages of the exemplary embodiments will be set forth in the detailed description, will be obvious from the detailed description, or may be learned by practicing the exemplary embodiments.

### BRIEF DESCRIPTION OF THE DRAWING FIGURES

The above and/or other aspects will be more apparent by describing in detail exemplary embodiments, with reference to the accompanying drawings, in which:

FIG. 1 is a schematic cross-sectional view illustrating a power board according to a first exemplary embodiment;

FIG. 2 is a schematic perspective view illustrating a supporting member according to the first exemplary embodiment;

FIGS. 3A and 3B are schematic perspective views illustrating a process of manufacturing a supporting member according to the first exemplary embodiment;

FIGS. 4A and 4B are schematic perspective views illustrating a process of mounting a supporting member in a board according to the first exemplary embodiment;

FIG. 5 is a schematic perspective view illustrating a supporting member included in a power board according to a second exemplary embodiment;

FIG. 6 is a schematic perspective view illustrating a supporting member included in a power board according to a third exemplary embodiment and

FIG. 7 is a schematic cross-sectional view illustrating a liquid crystal display apparatus according to exemplary embodiments.

### DETAILED DESCRIPTION OF THE EXEMPLARY EMBODIMENTS

Hereinafter, exemplary embodiments will be described in more detail with reference to the accompanying drawings.

In the following description, same reference numerals are used for the same elements when they are depicted in different drawings. The matters defined in the description, such as detailed construction and elements, are provided to assist in a comprehensive understanding of the exemplary embodiments. Thus, it is apparent that the exemplary embodiments can be carried out without those specifically defined matters. Further, functions or elements known in the related art are not described in detail, because they would obscure the exemplary embodiments with unnecessary detail.

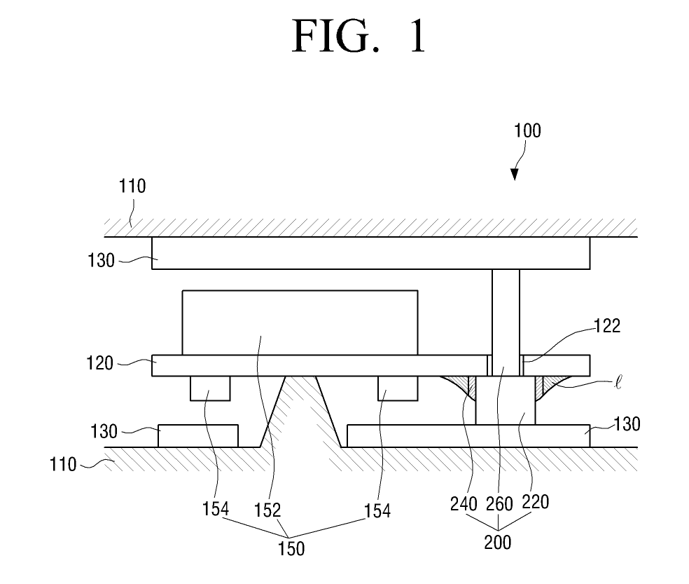

FIGS. 1 to 4B illustrate a power board and a supporting member in various aspects according to a first exemplary embodiment.

First, a power board according to an exemplary embodiment will now be described below.

Referring to FIGS. 1, 2, 3A, 3B, 4A, and 4B, a power board 100 includes a board housing 110 configured to form an appearance, a board 120 mounted in an inside of the board housing 110, a plurality of parts 150 mounted in the board 120, and a supporting member 200 configured to be mounted in the board 120 and support the board 120 to prevent the parts 150 from being damaged.

A plurality of insulating units 130 are mounted on an inner surface of the board housing 110 to prevent electricity generated in the board 120 in which the parts 150 are mounted from being conducted to the board housing 110.

The parts 150 include a top part 152 mounted on a top of the board 120 and at least one bottom part 154 mounted on a bottom of the board 120.

The supporting member 200 is mounted in the board 120 by using a surface mount technology (SMT) process, and then soldered and fixed to the board 120. The SMT process is a process by which parts are automatically mounted in a printed circuit board (PCB) using one or multiple equipment. In this process, the parts are mounted in the PCB and then joined to the PCB to electrically connect the parts by using a bonding or soldering. In particular, in the exemplary embodiment illustrated in FIG. 1, the supporting member 200 is mounted on the board 120 together with parts among the parts 150, which are mounted on the board 120 by using a SMT process, and then jointed by a soldering 1. Accordingly, the supporting member 200 includes a material which is heat-resistant at a soldering temperature. In addition, the supporting member 200 includes an insulator which prevents a flow of electricity through the supporting member 200.

The supporting member 200 includes a lower supporting unit 220 configured to support the bottom of the board 120 and a soldering unit 240 attached to a side of the lower supporting unit 220 and soldered and fixed to a solder area 126 on the bottom of the board 120. The lower supporting unit 220 may include a thermosetting resin and the soldering unit 240 may include a solderable material.

The lower supporting unit 220 has a height which is greater than respective heights of the bottom parts 154, in order to prevent the bottom parts 154 mounted on the bottom of the board 120 from being damaged. Accordingly, the bottom parts 154 may be disposed to leave a space with respect to the board housing 110 or the insulting units 130. When a force is externally applied to a lower portion of the board housing 110, the lower supporting unit 220 primarily absorbs the force and prevents the force from being applied to the bottom parts 154.

The supporting member 200 may further include an upper supporting unit 260 configured to be formed on the lower supporting unit 220 and to support the board 120.

A through-hole 122 is formed in the board 120 to allow the upper supporting unit 260 to penetrate therethrough and to be inserted into the through-hole 122. The through-hole 122 has a width which is smaller than a corresponding width of the lower supporting unit 220, thereby preventing the lower supporting member 220 from slipping through the through-hole 122. In addition, the through-hole 122 has a width which allows the upper supporting unit 260 to be inserted therein.

The upper supporting unit 260 has a height which is greater than a height of the top part 152, which is mounted on the top of the board 120, in order to prevent the top part 152 from being damaged, similarly as described above with respect to the lower supporting unit 220. Accordingly, similarly as with the lower part 154, the top part 152 may be disposed to leave a space with respect to the board housing 110 or the insulating unit 130. When a force is externally applied to an upper portion of the board housing 110, the upper supporting unit 260 primarily absorbs the force and prevents the force from being applied to the top part 152.

The upper supporting unit 260 may include a thermosetting resin, similarly as described above with respect to the lower supporting unit 220. The upper supporting unit 260 may be molded integrally with the lower supporting unit 220.

The soldering unit 240 is formed such that the soldering unit 240 is mounted to penetrate the lower supporting unit 220, and both of a first end and a second end opposite the first end of the soldering unit 240 are bent to be in contact with solder areas 126.

A plurality of soldering units 240 may be mounted in the lower supporting unit 220 such that each respective soldering unit 240 is spaced apart from a next soldering unit 240 by a predetermined distance.

A process of manufacturing the supporting member 200 according to the first exemplary embodiment will now be described below.

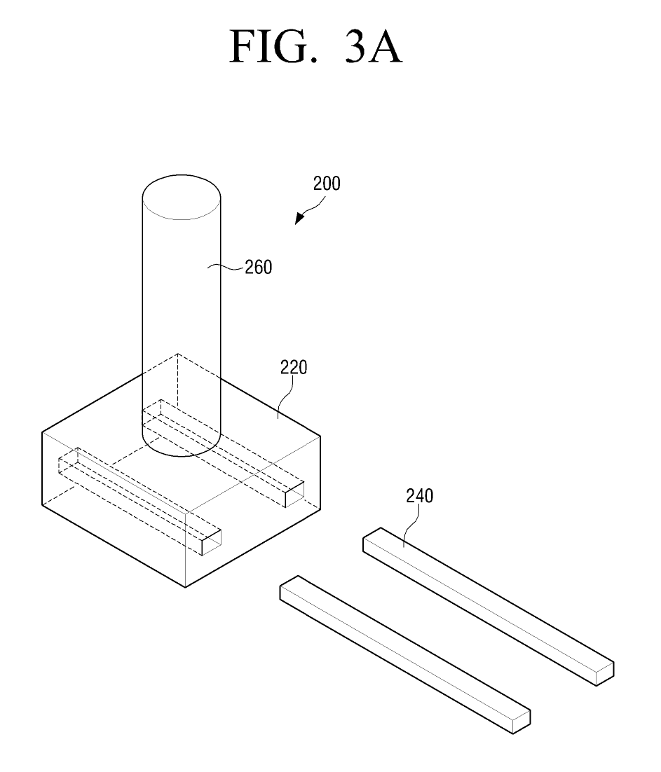

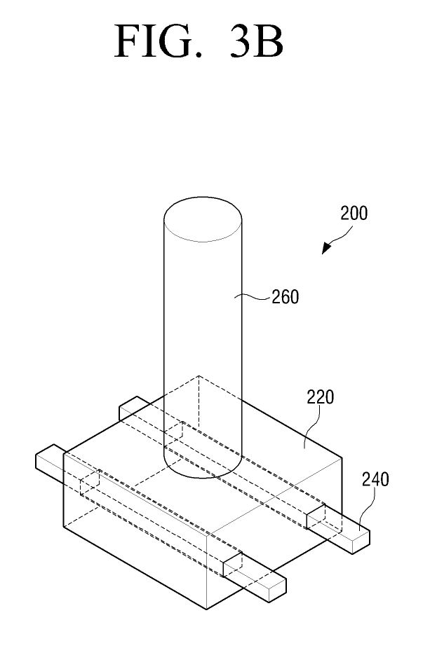

Referring to FIGS. 3A and 3B, the lower supporting unit 220 and the upper supporting unit 260 are first integrally formed. An insertion groove is formed in the lower supporting unit 220 to allow the at least one soldering unit 240 to be inserted. The at least one soldering unit 240 is inserted into the insertion groove of the lower supporting unit 220 such that both ends of the at least one soldering unit 240 protrude outwardly from the lower supporting unit 220.

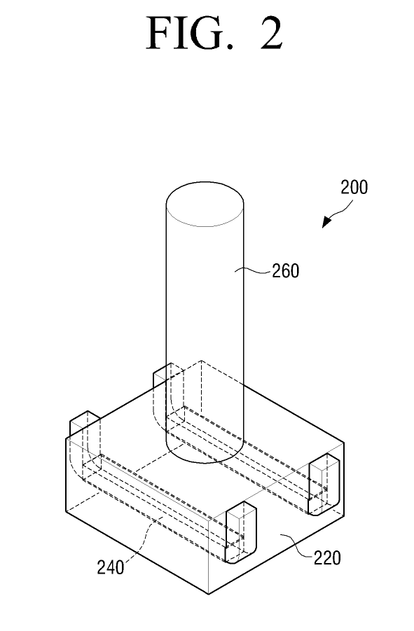

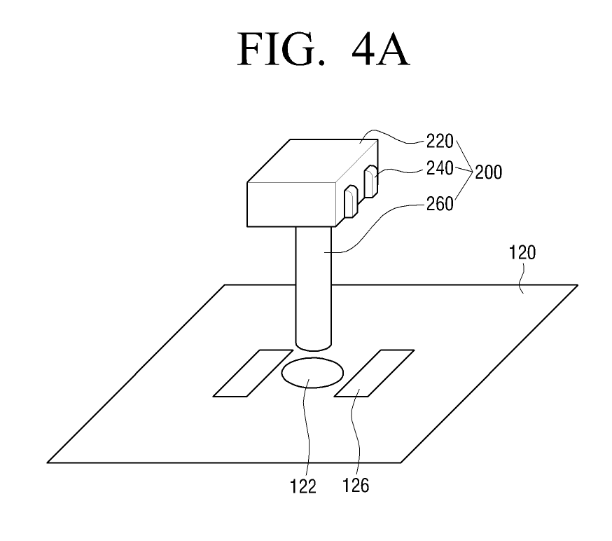

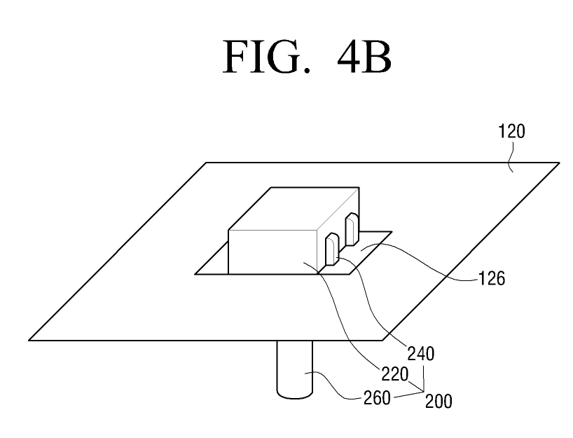

As shown in FIG. 2, the protruding both ends of the at least one soldering unit 240 are bent and extend upwardly such that the both ends of the at least one soldering unit 240 are in contact with the solder areas 126 (see also FIG. 4A and FIG. 4B).

A process of mounting the supporting member 200 in the board 120 according to the first exemplary embodiment will now be described below.

As shown in FIGS. 4A and 4B, the upper supporting unit 260 of the supporting member 200 is inserted through the through-hole 122 of the board 120, and the lower supporting unit 220 is adhered to and mounted on the board 120 to allow the soldering unit 240 to be in contact with the solder area 126. In particular, the mounting of the supporting member 200 is performed by using an SMT process. Although not shown, similarly as described above with respect to the supporting member 200, each of the bottom parts 154 is mounted on the bottom surface of the board 120 by using the SMT process. Accordingly, the process of mounting the bottom parts 154, which is performed by using the SMT process, effectively causes the supporting member 200 to be mounted in the board 120.

When the bottom parts 154 and the supporting member 200 are mounted on the bottom surface of the board 120, a soldering process is performed on the bottom surface of the board 120 so that the bottom part 154 and the supporting member 200 are fixed to the board 120. Accordingly, because the supporting member 200 is mounted and fixed in conjunction with the mounting of the bottom parts 154, a separate process for mounting the supporting member 200, such as a manual insertion process, is not required, thereby resulting in an increase in efficiency in a process and productivity.

Although the mounting of the top part 152 in the board 120 is not illustrated, in general, the top part 154 is mounted on the top of the board 120 prior to executing the SMT process for mounting the bottom parts 154 and the supporting member 200.

A supporting member included in a power board according to another exemplary embodiment will be described below. The components having the same structure as in the above-described exemplary embodiment are denoted by the same reference numerals, and thus the redundant description will be omitted or simplified. Further, the supporting member according to the exemplary embodiment will be described below by providing details relating to the differences between exemplary embodiments.

A supporting member according to a second exemplary embodiment will be now described.

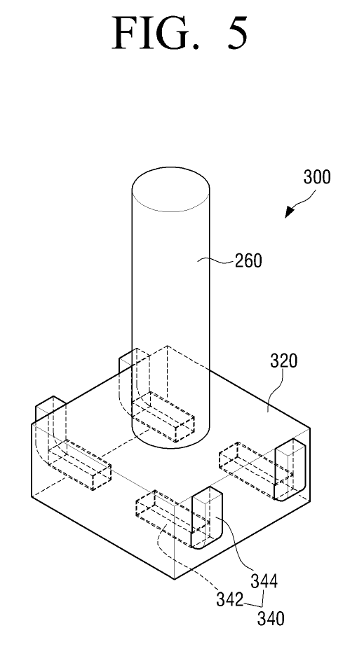

Referring to FIG. 5, a supporting member 300 according to the second exemplary embodiment includes a lower supporting unit 320, an upper supporting unit 260 formed on the lower supporting unit 320, and a plurality of soldering units 340 mounted in the lower supporting unit 320.

Each respective soldering unit 340 has an “L”-character shape such that one end 342 of the respective soldering unit 340 is inserted into an insertion groove formed in the lower supporting unit 320 and the other end 344 of the respective soldering unit 340 is in contact with a solder area (126 of FIGS. 4A and 4B). By contrast with the first exemplary embodiment, the supporting member 300 according to the second exemplary embodiment is formed such that each respective soldering unit 340 does not completely penetrate an inside of the lower supporting unit 320; instead, only the one end 342 of the respective soldering unit 340 is inserted into the insertion groove provided in the lower supporting unit 320. Accordingly, when the supporting member 300 according to the second exemplary embodiment is manufactured, because it is not necessary to mold the lower supporting unit 320 to enable the respective soldering units 340 to completely penetrate the inside of the lower supporting unit 320, a manufacture of the lower supporting unit 320 is simplified.

Next, a supporting member according to a third exemplary embodiment will be described below.

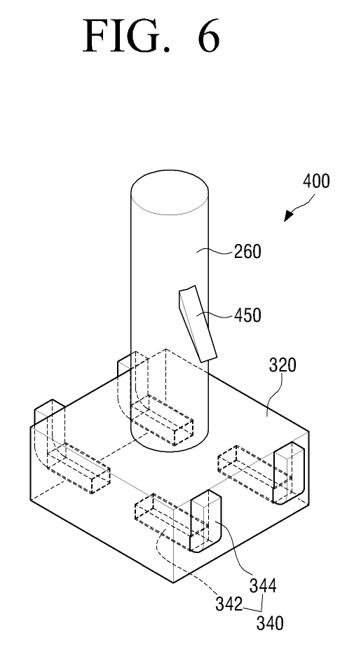

Referring to FIG. 6, a supporting member 400 according to the third exemplary embodiment further includes a hook unit 450 disposed on one side of the upper supporting unit 260, by contrast with the second exemplary embodiment.

If the supporting member 400 is not firmly fixed to the board due to a soldering failure relating to the soldering unit 340 after the mounting of the supporting member 400, the hook unit 450 serves to prevent the upper supporting unit 260 from slipping through the through-hole when the supporting member 400 is detached from the board. In particular, even when the supporting member 400 according to the third exemplary embodiment might otherwise become detached from the board, the hook unit 450 effectively locks onto the top of the board to prevent the supporting member 400 from becoming detached from the board.

The hook unit 450 may include the same material as the soldering unit 340 to provide ease of manufacturing, thereby enabling the hook unit 450 to be mounted in the upper supporting unit 260 when the soldering unit 340 is mounted in the lower supporting unit 320.

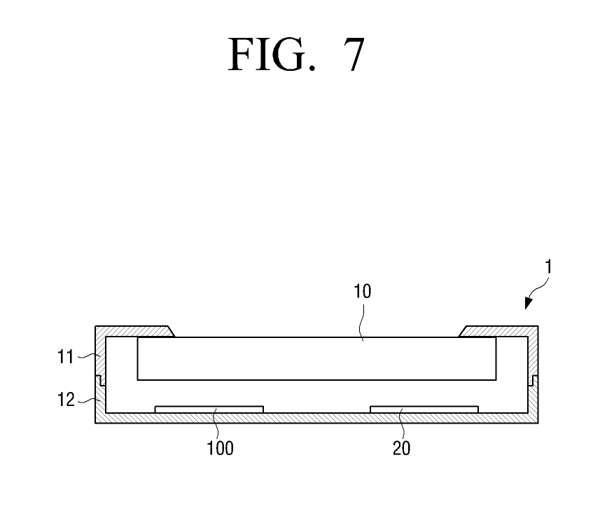

FIG. 7 is a schematic cross-sectional view illustrating a liquid crystal display (LCD) apparatus according to exemplary embodiments.

A LCD television (TV) has been illustrated as the LCD apparatus 1 of FIG. 7. However, those skilled in the art will understand that the LCD apparatus 1 according to exemplary embodiments may include any one of many different types of display apparatuses, such as, for example, a computer monitor.

Referring to FIG. 7, the LCD apparatus 1 includes an upper housing 11 and a lower housing 12. The housings 11 and 12 contain the power board 100 according to one or more of the above-described exemplary embodiments. In addition, a panel assembly 10, including a liquid crystal panel and a control board 20 configured to control an operation of the LCD apparatus 1, are disposed in an inside of the housings 11 and 12. In FIG. 7, although the power board 100 and the control board 20 are illustrated, other circuit boards may be additionally included in the inside of the LCD apparatus 1.

The foregoing exemplary embodiments and advantages are merely exemplary and are not to be construed as limiting the present inventive concept. The exemplary embodiments can be readily applied to other types of apparatuses. Also, the description of the exemplary embodiments is intended to be illustrative, and not to limit the scope of the claims, and many alternatives, modifications, and variations will be apparent to those skilled in the art.

1. A power board, comprising:
a board housing;
a board included in an inside of the board housing;
a plurality of parts mounted in the board; and
a supporting member which is mounted in the board and which supports the board to prevent each of the plurality of parts from being damaged,
wherein the supporting member includes a supporting member mounted by using a surface mounted technology (SMT) process.

2. The power board as claimed in claim 1, wherein the supporting member mounted by using the SMT process is soldered and fixed to the board.

3. The power board as claimed in claim 2, wherein the supporting member includes:
a lower supporting unit which supports a bottom of the board; and
a soldering unit attached to a side of the lower supporting unit and which is soldered and fixed to the bottom of the board.

4. The power board as claimed in claim 2, wherein the supporting member further includes an upper supporting unit which is formed on the lower supporting unit and which supports a top of the board.

5. The power board as claimed in claim 3, wherein a height of the lower supporting unit is greater than a height of each part mounted on the bottom of the board.

6. The power board as claimed in claim 4, wherein the board includes a through-hole which allows the upper supporting unit to be inserted therethrough, and the lower supporting unit has a width greater than a width of the throughhole.

7. The power board as claimed in claim 6, wherein a height of a portion of the upper supporting unit extending from the top of the board is greater than a height of each part mounted on the top of the board.

8. The power board as claimed in claim 6, wherein the supporting member further includes a hook unit which prevents the upper supporting unit from slipping through the through-hole.

9. The power board as claimed in claim 3, wherein the soldering unit is formed such that the soldering unit is mounted to penetrate the lower supporting unit, and both of a first end and a second end opposite the first end of the soldering unit are bent to be in contact with the bottom of the board.

10. The power board as claimed in claim 9, wherein each of a plurality of soldering units is mounted in the lower supporting unit such that each respective soldering unit is spaced apart from a next soldering unit by a predetermined distance.

11. The power board as claimed in claim 3, wherein the soldering unit is formed such that a first end of the soldering unit is inserted into the lower supporting unit and a second end opposite the first end of the soldering unit is in contact with the bottom of the board.

12. The power board as claimed in claim 11, wherein each of a plurality of soldering units is mounted in the lower supporting unit such that each respective soldering unit is spaced apart from a next soldering unit by a predetermined distance.

13. The power board as claimed in claim 2, wherein the supporting member includes an insulator formed by using a thermosetting resin, which includes a material which is heat-resistant at a soldering temperature.

14. A liquid crystal display apparatus comprising the power board according to claim 1.

15. A method of manufacturing a power board, comprising:
mounting an upper part on a top of a board;
mounting a lower part and a supporting member which supports the board to prevent the upper and lower parts from being damaged in a bottom of the board by using a surface mount technology (SMT) process; and
soldering the lower part and the supporting member on the bottom of the board.

16. The method as claimed in claim 15, wherein the supporting member includes:
a lower supporting unit which supports the bottom of the board; and
a soldering unit attached to a side of the lower supporting unit and which is soldered and fixed to the bottom of the board,
wherein a height of the lower supporting unit is greater than a height of each part mounted on the bottom of the board.

17. The method as claimed in claim 16, wherein the supporting member further includes an upper supporting unit which is formed on the lower supporting unit and which supports a top of the board,
wherein a height of a portion of the upper supporting unit extending from the top of the board is greater than a height of each part mounted on the top of the board.

18. The method as claimed in claim 17, further comprising forming a hook unit which prevents the upper supporting unit from slipping through a through-hole.

19. The method as claimed in claim 16, wherein the soldering unit is mounted to penetrate the lower supporting unit and both of a first end and a second end opposite the first end of the soldering unit are bent to be in contact with the bottom of the board.

20. The method as claimed in claim 16, wherein the soldering unit is formed such that a first end of the soldering unit is inserted into the lower supporting unit and a second end opposite the first end of the soldering unit is in contact with the bottom of the board.
